(19) United States
(12) Patent Application Publication
(10) Pub. No.: US 2010/0132762 A1
(43) Pub. Date: Jun. 3, 2010

(54) ENVIRONMENTAL BARRIER COATING FOR ORGANIC SEMICONDUCTOR DEVICES AND METHODS THEREOF

(75) Inventors: SAMUEL GRAHAM, JR., Lithonia, GA (US); Bernard Kippelen, Decatur, GA (US); Namsu Kim, Altanta, GA (US); Benoit Domercq, Waterloo (BE)

Correspondence Address: TROUTMAN SANDERS LLP;5200 BANK OF AMERICA PLAZA, 600 PEACHTREE STREET, N.E., SUITE 5200, ATLANTA, GA, 30308-2216, US

(73) Assignee: Georgia Tech Research Corporation, Atlanta, GA (US)

(21) Appl. No.: 12/629,009

(22) Filed: Dec. 1, 2009

Related U.S. Application Data
(60) Provisional application No. 61/119,200, filed on Dec. 2, 2008.

(51) Int. Cl. H01L 31/042; B32B 9/04; B32B 27/32; B32B 27/38; B32B 27/30; B32B 27/00; B32B 27/40; B32B 5/00; H01L 31/04; C23C 16/44; C23C 16/513; H01J 1/62; H01L 51/50; H01L 51/56; H01L 51/05

(52) U.S. Cl. 136/244; 428/411.1; 428/702; 428/698; 428/689; 428/523; 428/413; 428/522; 428/473.5; 428/423.1; 428/447; 428/332; 136/256; 427/248.1; 427/569; 427/66; 427/74; 427/58; 313/504; 257/40; 438/38; 438/99; 257/E51.022; 257/E51.005

(57) ABSTRACT

Improved environmental barrier coatings and improved organic semiconductor devices employing the improved environmental barrier coatings are disclosed herein. Methods of making and using the improved coatings and devices are also described. An improved environmental barrier coating generally includes a primary barrier layer, a secondary barrier layer disposed on the primary barrier layer, and a passivation layer disposed on the secondary barrier layer. The secondary barrier layer is formed using atomic layer deposition.

### CROSS-REFERENCE TO RELATED APPLICATION

The present application claims the benefit of U.S. Provisional Patent Application No. 61/119,200, filed 2 Dec. 2008, and entitled “Environmental Barrier Coating for Organic Semiconductor Devices and Method Thereof”, which is hereby incorporated by reference in its entirety as if fully set forth below.

### STATEMENT OF FEDERALLY SPONSORED RESEARCH

This invention was made with United States Government support under agreement number DMR-0120967 awarded by the National Science Foundation. The United States Government has certain rights in this invention.

### TECHNICAL FIELD

The various embodiments of the present invention relate generally to improved organic devices and their associated fabrication processes, and more particularly to improved environmental barrier films and to methods for making such films.

### BACKGROUND

Organic semiconductor devices can experience significant degradation from exposure to environmental conditions. Specifically, oxygen and water vapor are known to cause corrosion or other degradation due to photo-oxidation, which can severely limit the shelf-life and operational stability of many organic electronics devices (e.g., photovoltaic cells, light-emitting diodes, displays, field-effect transistors, and like devices made from organic materials). For example, organic photovoltaic (OPV) cells are promising alternative energy sources that have been fabricated and tested largely in controlled, laboratory environments. Such cells will be subjected to a variety of uncontrollable conditions when deployed in actual, real world applications. Thus OPV cells, like other organic semiconductor devices, must be packaged with environmental barrier coatings to delay or completely prevent degradation.

Packaging technologies that have been developed for inorganic optoelectronic materials cannot be applied directly to organic-based materials because they often involve processing temperatures that are too high for organic materials and that would damage the organic layers during the fabrication process. Other low temperature encapsulation techniques include placing the organic solar cell between two glass slides, which are good barriers to oxygen and water vapor, and sealing the edges with an adhesive (e.g., epoxy). This packaging approach, however, adds weight and rigidity, thereby precluding use of a device packaged as such in applications that require flexibility of the device. The desired encapsulation technique must not only block oxygen and water effectively, but should be transparent, thin, flexible and lightweight to take full advantage of the potential of the device in practical applications.

Transparent thin-film encapsulation of organic electronics has focused primarily on the development of high quality single layer barrier films as well as multilayer thin films, which contain alternating layers of inorganic and organic films. For example, methods such as plasma-enhanced chemical vapor deposition (PECVD) or sputter deposition processing have been employed to create inorganic thin films, which are used in barrier coatings. However, these films are prone to defects, which facilitate the permeation of water vapor and oxygen, resulting in poor protection. To mitigate these effects, researchers have utilized multilayer films, which interrupt the growth of the inorganic layers by interposing a thin layer of an organic material. Such a multilayered structure causes discontinuities in the defect pathways through the encapsulation barrier, resulting in increased permeation resistance. Using such technology, effective water vapor transmission rates (WVTR) of about 10⁻⁶ grams per square meter per day (g/m²/day) have been obtained for temperatures up to 60° C. and 90% relative humidity. With this approach, however, multiple bilayers (i.e., of the inorganic/organic films) are needed, leading to an increase in the complexity of processing these barrier films.

On the other hand, single layer barrier films of, for example, Al₂O₃, prepared using atomic layer deposition (ALD), have also shown great promise as barrier films. Reports have shown that the effective WVTR of such films on the order of 100 nanometers (nm) can range between about 10⁻³ to about 10⁻⁵ g/m²/day. While ALD-deposited films allow for higher quality inorganic films with fewer defects than seen in PECVD or sputtering, ALD suffers from slow deposition rates, which results in increased deposition times.

There, accordingly, remains a need for improved processes to fabricate barrier layer coatings that will exhibit high barrier performance (e.g., WVTR less than about 10⁻⁴ g/m²/day), while minimizing the deposition time and the number of deposition steps needed to produce the barrier film in order to reduce processing complexities and cost. In addition, the barrier coatings, which are produced using such methods, should be capable of being deposited directly onto an organic device, such as an organic photovoltaic cell, at a temperature that does not degrade the performance of the device. It is to the provision of such processes and coatings that the various embodiments of the present invention are directed.

### BRIEF SUMMARY

The various embodiments of the present invention relate to improved organic devices and to processes for making the improved devices. That is, some embodiments are directed to improved environmental barrier coatings. Other embodiments are directed to improved organic devices, which include the improved environmental barrier coatings. Still other embodiments are directed to methods of making and using the improved environmental barrier coatings and the improved organic devices.

According to some embodiments of the present invention, an environmental barrier coating can include a primary barrier layer disposed on a surface of an organic component, a secondary barrier layer disposed on the primary barrier layer, and a passivation layer disposed on the secondary barrier layer.

The primary barrier layer can be a non-conformal layer. The primary barrier layer can have a thickness of about 20 nanometers to about 500 nanometers. Depending on its composition, the primary barrier layer can be formed using plasma enhanced chemical vapor deposition.

In some situations, the primary barrier layer is formed from a metal oxide, metal nitride, metal oxynitride, or a combination comprising at least one of the foregoing. For example, the primary barrier layer can be formed from an oxide, nitride or oxynitride of silicon. In other situations, the primary barrier layer is formed from a fluoropolymer, polyolefin, epoxide polymer, acrylate polymer, polyimide, polyurethane, silicone polymer, parylene, a copolymer thereof, or a combination comprising at least one of the foregoing.

The secondary barrier layer can be a conformal layer formed by atomic layer deposition. The secondary barrier layer can have a thickness of less than or equal to about 50 nanometers. In some cases, the secondary barrier layer can have a thickness of less than or equal to about 15 nanometers. The secondary barrier layer can be formed from a metal oxide, metal nitride, metal oxynitride, metal sulfide, or a combination comprising at least one of the foregoing. For example, the secondary barrier layer can be formed from an oxide of aluminum, silicon, zinc, zirconium, hafnium, titanium, a solid solution thereof, or a combination comprising at least one of the foregoing.

The passivation layer can serve to reduce exposure of the primary and secondary barrier layers to moisture and oxygen. In some cases, the passivation layer is a conformal layer. The passivation layer can have a thickness of at least about 100 nm. In some situations, the passivation layer is formed from a metal oxide, metal nitride, metal oxynitride, or a combination comprising at least one of the foregoing. In other situations, the passivation layer is formed from a fluoropolymer, polyolefin, epoxide polymer, acrylate polymer, polyimide, polyurethane, silicone polymer, parylene, a copolymer thereof, or a combination comprising at least one of the foregoing. For example, the passivation layer can be formed from parylene C.

The environmental barrier coating can also include an optional buffer layer interposed between the primary barrier layer and the surface of the organic component, wherein the buffer layer is a non-conformal layer. The buffer layer can be formed from a metal oxide, metal nitride, metal oxynitride, or a combination comprising at least one of the foregoing. In certain situations, the buffer layer is formed from an oxide, nitride or oxynitride of silicon. In other situations, the buffer layer is formed from a fluoropolymer, polyolefin, epoxide polymer, acrylate polymer, polyimide, polyurethane, silicone polymer, parylene, a copolymer thereof, or a combination comprising at least one of the foregoing.

The overall environmental barrier coating can have an effective water vapor transmission rate of less than 10⁻⁴ grams per square meter per day measured at about 20 degrees Celsius and at about 50 percent relative humidity. In some cases, the environmental barrier coating can have an effective water vapor transmission rate of less than 10⁻⁴ grams per square meter per day for temperatures up to about 60 degrees Celsius and relative humidities up to about 90 percent relative humidity.

With respect to the organic component, it can be an organic substrate or an organic semiconductor device. In some cases, the organic component can be flexible. That is, the organic component can be a flexible organic substrate or a flexible organic semiconductor device. The organic substrate can be a polymer substrate. The organic semiconductor device can be an organic light-emitting diode, organic light-emitting display, organic photovoltaic cell, an organic photovoltaic module, organic memory device, organic field-effect transistor, or an organic electronic circuit comprising at least one of the foregoing organic components.

According to other embodiments of the present invention, an environmental barrier coating can include a primary barrier layer disposed on a surface of an organic component, wherein the primary barrier layer is a non-conformal layer formed by plasma enhanced chemical vapor deposition having a thickness of about 20 nanometers to about 500 nanometers.

The environmental barrier coating can also include a secondary barrier layer disposed on the primary barrier layer, wherein the secondary barrier layer is a conformal layer formed by atomic layer deposition having a thickness of less than or equal to about 50 nanometers. In some cases, the thickness of the secondary barrier layer is less than or equal to about 15 nanometers.

In addition, the environmental barrier coating can also include a passivation layer disposed on the secondary barrier layer, wherein the passivation layer reduces exposure of the primary and secondary barrier layers to moisture and oxygen.

The environmental barrier coating can optionally include a buffer layer interposed between the primary barrier layer and the surface of the organic component, wherein the buffer layer is a non-conformal layer.

The overall environmental barrier coating can have an effective water vapor transmission rate of less than 10⁻⁴ grams per square meter per day measured at about 20 degrees Celsius and at about 50 percent relative humidity. In some cases, the environmental barrier coating can have an effective water vapor transmission rate of less than 10⁻⁴ grams per square meter per day for temperatures up to about 60 degrees Celsius and relative humidities up to about 90 percent relative humidity.

With respect to the organic component, it can be an organic substrate or an organic semiconductor device. In some cases, the organic component can be flexible. That is, the organic component can be a flexible organic substrate or a flexible organic semiconductor device. The organic substrate can be a polymer substrate. The organic semiconductor device can be an organic light-emitting diode, organic light emitting display, organic photovoltaic cell, an organic photovoltaic module, organic memory device, organic field-effect transistor, or an organic electronic circuit comprising at least one of the foregoing organic components.

According to some embodiments of the present invention, a method of fabricating an environmental barrier coating can include disposing a non-conformal primary barrier layer on a surface of an organic component. The primary barrier layer can be disposed on the surface of the organic component by plasma enhanced chemical vapor deposition.

The method can also include disposing a conformal secondary barrier layer on the primary barrier layer by atomic layer deposition.

The method can also include disposing a passivation layer on the secondary barrier layer, wherein the passivation layer reduces exposure of the primary and secondary barrier layers to moisture and oxygen.

The method can optionally include disposing a buffer layer on the surface of the organic component, wherein the non-conformal primary buffer layer is then disposed on the buffer layer. The buffer layer can be disposed on the surface of the organic component by plasma enhanced chemical vapor deposition.

One or more of the primary barrier layer, secondary barrier layer, passivation layer, and optional buffer layer can be disposed at a temperature of less than or equal to about 300 degrees Celsius.

With respect to the organic component, it can be an organic substrate or an organic semiconductor device. In some cases, the organic component can be flexible. That is, the organic component can be a flexible organic substrate or a flexible organic semiconductor device. The organic substrate can be a polymer substrate. The organic semiconductor device can be an organic light-emitting diode, organic light emitting display, organic photovoltaic cell, an organic photovoltaic module, organic memory device, organic field-effect transistor, or an organic electronic circuit comprising at least one of the foregoing organic components.

To make a sandwich structure, where the organic component is an organic substrate, the method can further include disposing an organic semiconductor device on the passivation layer, followed by disposing a different non-conformal primary barrier layer on the organic semiconductor device, disposing a different conformal secondary barrier layer on the different primary barrier layer by atomic layer deposition, and disposing a different passivation layer on the different secondary barrier layer, wherein the different passivation layer reduces exposure of the different primary and different secondary barrier layers to moisture and oxygen.

It should be noted that the non-conformal primary barrier layer and the different non-conformal primary barrier layer can have the same composition. Similarly, the conformal secondary barrier layer and the different conformal secondary barrier layer can have the same composition. Further, the passivation layer and the different passivation layer can have the same composition.

The method of making the sandwich structure can also include disposing a buffer layer on the organic semiconductor device, wherein the different non-conformal primary buffer layer is then disposed on the buffer layer.

Other aspects and features of embodiments of the present invention will become apparent to those of ordinary skill in the art, upon reviewing the following description of specific, exemplary embodiments of the present invention in conjunction with the accompanying figures.

### BRIEF DESCRIPTION OF THE DRAWINGS

FIG. 1 is a schematic illustration of an environmental barrier coating in accordance with some embodiments of the present invention.

FIG. 2 is a schematic illustration of a sandwich structure incorporating an organic semiconductor device interposed between two structures formed from an environmental barrier coating disposed on a flexible substrate in accordance with some embodiments of the present invention.

FIGS. 3A-B are a schematic illustration of the environmental barrier coating structure for Ca samples which are used to measure the effective WVTR of the encapsulation layers when utilized on (A) glass and (B) polymer substrates in accordance with some embodiments of the present invention.

FIG. 4A is a schematic illustration of an encapsulated Ca sensor in accordance with some embodiments of the present invention.

FIG. 4B is a graph showing the change in conductance measured on three Ca sensors, prepared as shown in FIG. 4A, as a function of time in accordance with some embodiments of the present invention.

FIG. 5A is a schematic illustration of an encapsulated Ca sensor in accordance with some embodiments of the present invention.

FIG. 5B is a graph showing the change in conductance measured on three Ca sensors, prepared as shown in FIG. 5A, as a function of time in accordance with some embodiments of the present invention.

FIG. 6A is a schematic illustration of an encapsulated Ca sensor in accordance with some embodiments of the present invention.

FIG. 6B is a graph showing the change in conductance measured on three Ca sensors, prepared as shown in FIG. 6A, as a function of time in accordance with some embodiments of the present invention.

FIG. 7A is a schematic illustration of an encapsulated Ca sensor in accordance with some embodiments of the present invention.

FIG. 7B is a graph showing the change in conductance measured on three Ca sensors, prepared as shown in FIG. 7A, as a function of time in accordance with some embodiments of the present invention.

FIG. 8A is schematic illustration of a Ca sensor encapsulated by a 100 nanometer thick film of Al₂O₃ grown by atomic layer deposition (ALD).

FIG. 8B is schematic illustration of a Ca sensor encapsulated by a 1 micrometer thick buffer film of parylene and a 100 nanometer thick film of Al₂O₃ grown by ALD.

FIG. 8C is schematic illustration of a Ca sensor encapsulated by a 1 micrometer thick buffer film of parylene, a 100 nanometer thick film of Al₂O₃ grown by ALD, and another 1 micrometer thick buffer film of parylene.

FIG. 9 is a graph showing the relative change in the conductance versus time of encapsulated Ca samples as described in FIGS. 8B and 7C.

FIG. 10 is a graph showing the change in conductance measured on three Ca sensors, prepared as shown in FIG. 8C, as a function of time.

FIG. 11 is a schematic representation of an encapsulated organic photovoltaic cell in accordance with some embodiments of the present invention.

FIG. 12 is a graph showing electrical characteristics measured in the dark (empty shapes) and under illumination (filled shapes) for various solar cells having the structure shown in FIG. 11, both before and after deposition of an environmental barrier coating in accordance with some embodiments of the present invention. The inset of FIG. 12 displays the overlap of electrical characteristics for six devices before and after encapsulation in the dark and under illumination.

FIGS. 13A-C include graphs showing the relative change in (A) power conversion efficiency, (B) fill factor, and (C) short-circuit current density of various solar cells having the structure shown in FIG. 11 after exposure to an ambient atmosphere.

### DETAILED DESCRIPTION

Referring now to the figures, wherein like reference numerals represent like parts throughout the several views, exemplary embodiments of the present invention will be described in detail. Throughout this description, various components may be identified having specific values or parameters. These items, however, are provided as exemplary embodiments. Indeed, the exemplary embodiments do not limit the various aspects and concepts of the present invention as many comparable parameters, sizes, ranges, and/or values may be implemented. The terms “first,” “second,” “primary,” “secondary,” “top,” “bottom,” “distal,” “proximal,” and the like, do not denote any order, quantity, or importance, but rather are used to distinguish one element from another. Further, the terms “a,” “an,” and “the” do not denote a limitation of quantity, but rather denote the presence of “at least one” of the referenced item.

As described above, the various embodiments of the present invention relate to improved organic semiconductor devices and to processes for making the improved devices. Specifically, improved environmental barrier coatings are provided. Further, organic semiconductor devices incorporating the improved environmental barrier coatings are also provided. Their methods of manufacture and use are also described.

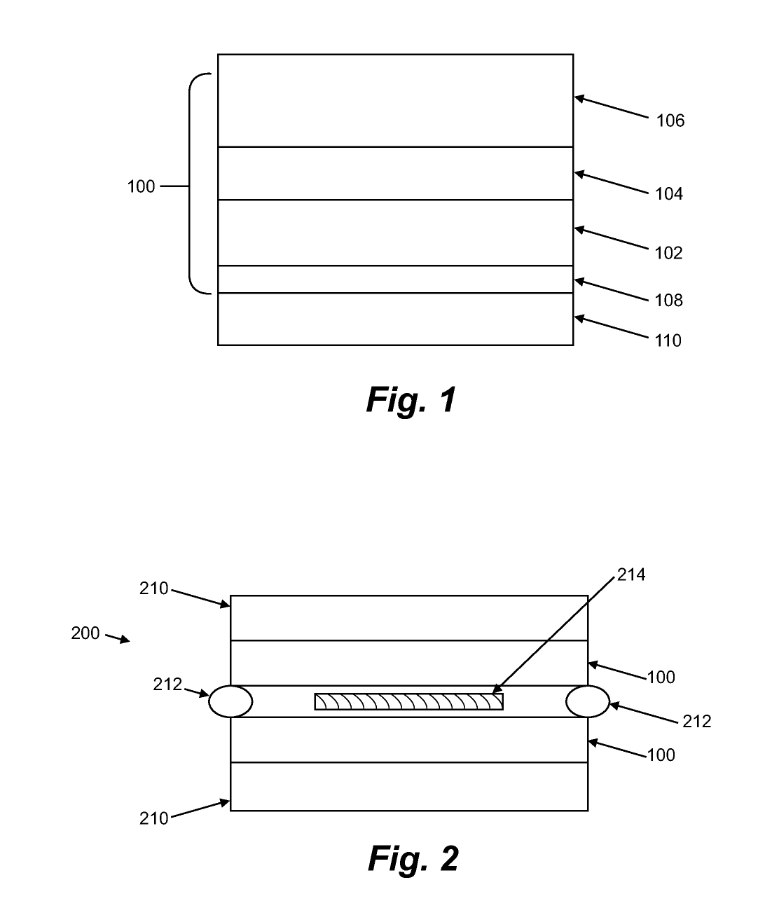

The environmental barrier coatings described herein are generally multilayer coatings. A cross-section of a multilayer environmental barrier coating, according to some embodiments of the present invention, is shown in FIG. 1. The multilayer environmental barrier coating, which is designated by reference numeral 100, generally includes a primary barrier layer 102, a secondary barrier layer 104, and a passivation layer 106.

The primary barrier layer 102 of the multilayer environmental barrier coating 100 is a non-conformal layer disposed on at least a portion of a surface of an organic component 110. The organic component 110 can be chosen from an organic substrate or an organic semiconductor device.

If the organic component 110 is an organic substrate, the multilayer environmental barrier coating 100 can serve to provide improved barrier properties to the organic substrate 110. In certain exemplary situations, the organic substrate 110 is a flexible organic substrate. It should be noted that if a device (regardless of its type) is disposed on the coated organic substrate (flexible or rigid), the device itself can also have a multilayered environmental barrier coating 100 disposed thereon.

For the purpose of the present invention, an “organic semiconductor device” is a device comprising a (i.e., at least one) organic semiconductor layer. Such devices include, but are not limited to, organic light-emitting diodes and displays, organic photovoltaic (OPV) cells and integrated modules, organic memory devices, organic field-effect transistors (FETs), organic electronic circuits comprised of organic FETs, and the like.

The primary barrier layer 102 can be fabricated from any material or composition that will not adversely affect the organic component (i.e., organic substrate or semiconductor device) 110 either during or after deposition of the primary barrier layer 102. That is, the primary barrier layer 102 should not be disposed on the surface of the organic component 110 in a manner that would cause a chemical reaction therebetween, initiate decomposition of a portion of the organic component 110, dissolve a portion (or individual components, if the organic component 110 is an of the organic semiconductor device) of the organic component 110, or the like. Similarly, the primary barrier layer 102, once deposited, should not generate reactive species that can cause portions of the organic component 110 to corrode, inhibit the optical transparency (if this feature is important for the particular application) of the organic component 110, decrease flexibility (if this feature is important for the particular application) of the organic component 110, or the like.

A number of materials meet the above criteria and can be used to form the primary barrier layer 102, as would be understood by those skilled in the art to which this disclosure pertains. For example, the primary barrier layer 102 can be formed from inorganic materials, including metal oxides, metal nitrides, metal oxynitrides, and the like. In another example, the primary barrier layer 102 can be formed from polymeric materials, including fluoropolymers, polyolefins, epoxide polymers, acrylate polymers, polyimides, polyurethanes, silicone polymers, parylenes, and the like. In situations where the organic component 110 is an organic semiconductor device, particularly exemplary polymers that can be used to form the primary barrier layer 102 involve those whose monomers are soluble in a solvent that is orthogonal to the solvent used to prepare a component of the organic semiconductor device 110 that is in contact with the primary barrier layer 102. One such category of polymer is a cyclized transparent optical polymer obtained by copolymerization of perfluoro (alkenyl vinyl ethers), an example of which is commercially available as CYTOP™ (Asahi Glass Co.).

The primary barrier layer 102 can have a thickness of about 20 to about 500 nanometers (nm). In some cases, where overall device thickness is a consideration, the primary barrier layer 102 can have a thickness of less than or equal to about 100 nm.

The secondary barrier layer 104 is disposed directly on the primary barrier layer 102. The secondary barrier layer 104 is a conformal layer that generally serves to fill in any defects (e.g., voids, pinholes, surface roughness, and the like) in the primary barrier layer 102.

The secondary barrier layer 104 can be fabricated from any material or composition that will not adversely affect the primary barrier layer 102 or the organic component 110 (e.g., such as by affecting operation of an organic semiconductor device) either during or after deposition of the secondary barrier layer 110. As with the primary barrier layer 102, a number of materials meet this condition and can be used to form the secondary barrier layer 104, as would be understood by those skilled in the art to which this disclosure pertains. For example, the secondary barrier layer 104 can be formed from a variety of inorganic materials, such as metal oxides, metal nitrides, metal oxynitrides, metal sulfides, and the like.

The secondary barrier layer 104 will have a thickness that is less than that of the primary barrier layer 102. Specifically, the secondary barrier layer can have an average thickness of less than or equal to about 50 nanometers (nm). Depending on the nature of the defects in the primary barrier layer 102, there may be situations where the thickness of the secondary barrier layer 104 must be at least 3 nm to overcome the surface roughness of the primary barrier layer 102. Further, given the possibility of long pinhole defects in the primary barrier layer 102, there will be situations where the local thickness of the secondary barrier layer will be greater than 50 nm.

The passivation or protection layer 106 is disposed directly on the secondary barrier layer 104. The passivation layer 106 generally serves to protect the primary and secondary barrier layers 102 and 104, respectively, from being adversely affected by any environmental conditions (e.g., heat, moisture, oxygen, and the like).

As a result of its function, the passivation layer 106 must be fabricated from a material or composition that will not adversely affect the primary barrier layer 102, the secondary barrier layer 104, or the organic component 110 either during or after deposition of the passivation layer 106. There are a number of materials that meet this condition and can be used to form the passivation layer 106, as would be understood by those skilled in the art to which this disclosure pertains. For example, the passivation layer 106 can be formed from a variety of inorganic materials, such as metal oxides, metal nitrides, metal oxynitrides, metal sulfides, and the like. In another example, the passivation layer 106 can be formed from polymeric materials, including fluoropolymers, polyolefins, epoxide polymers, acrylate polymers, polyimides, polyurethanes, silicone polymers, parylenes, and the like. Particularly exemplary polymers that can be used to form the passivation layer 106 involve those whose monomers are soluble in a solvent that is orthogonal to the solvent (if any) used to prepare a component of any of the underlying layers (i.e., of the multilayer environmental barrier coating 100 or of the organic component 110, when the organic component is an organic semiconductor device). One such category of polymer is a cyclized transparent optical polymer obtained by copolymerization of perfluoro (alkenyl vinyl ethers), an example of which is commercially available as CYTOP™ (Asahi Glass Co.). Depending on its constitution, the passivation layer 106 can be a conformal layer or a non-conformal layer.

There is no particular limitation on the thickness of the passivation layer 106. In order to provide adequate protection to the other components of the environmental barrier coating 100 and to the organic component 110, however, the passivation layer should be at least about 100 nm. When overall device thickness is a consideration, the passivation layer 106 can have a thickness of less than or equal to about 10 micrometers (μm). When overall device flexibility is a consideration, the passivation layer 106 can have a thickness of less than or equal to about 3 μm.

In situations where the organic component 110 is not substantially planar (e.g., when there are different components with different locations on the surface of an organic semiconductor device, when there are components with different thicknesses on the surface of an organic semiconductor device, when a portion of the surface of an organic semiconductor device has been etched, when the surface of the organic component has a high roughness, or the like), an optional buffer layer 108 can be disposed on the surface of the organic component 110 before the primary barrier layer 102 is disposed thereon. Thus, in embodiments where the optional buffer layer 108 is implemented, the primary barrier layer 102 is disposed on the buffer layer 108 instead of on the surface of the organic component 110. The buffer layer 108 functions to provide a planar surface upon which the primary barrier layer 102 is disposed.

The buffer layer 108 must have the same characteristics as the primary barrier layer 102 in the absence of the buffer layer 108. That is, the buffer layer 108 must be a non-conformal layer fabricated from a material or composition that will not adversely affect the organic component 110 either during or after deposition of the buffer layer 108. Just as with the primary barrier layer 102, the buffer layer 108 can be fabricated from a variety of materials. These include, for example, the inorganic and polymeric materials described above.

The thickness of the buffer layer 108 will depend on the overall topography of the organic component 110. If the surface of the organic component 110 has minimal variation, the buffer layer 108 can be as thin as about 50 nm. If the surface variation is quite large, then the buffer layer 108 can be as high as about 10 μm.

In making the multilayer environmental barrier coating 100, a variety of techniques can be used to prepare the individual layers. A process for preparing a multilayer environmental barrier coating 100 includes first providing an organic component 110 on which the primary barrier layer 102 can be disposed.

The primary barrier layer 102 can be disposed on the organic component 110 using any known technique for producing a non-conformal film or layer. Because the process by which the primary barrier layer 102 is disposed on the organic component 110 cannot adversely affect the organic component 110, certain conditions must be avoided during deposition of the primary barrier layer 102. These conditions include temperatures that could cause melting or decomposition of the organic component 110 (e.g., the substrate itself or components of an organic semiconductor device), moisture and/or oxygen levels that can cause absorption or reaction, and the like. For example, many organic substrates or components of organic semiconductor devices melt or decompose at temperatures above 300 degrees Celsius (° C.). Thus, the primary barrier layer 102 should be deposited on the organic component 110 at a temperature of less than or equal to about 300° C. In situations where energy expenditure is of concern, the temperature at which the primary barrier layer 102 is deposited on the organic component 110 can be less than or equal to about 200° C.

The techniques that can meet the above criteria include wet deposition techniques such as spin-coating, sol-gel, inkjet printing, and the like, as well as vapor deposition techniques such as chemical vapor deposition (CVD), metal organic chemical vapor deposition (MOCVD), plasma-enhanced CVD (PECVD), and the like. These techniques are known to those skilled in the art to which this disclosure pertains.

Once the primary barrier layer 102 has been deposited on the appropriate surface(s) of the organic component 110, the secondary barrier layer 104 can be fabricated. The secondary barrier layer 104 of the multilayer environmental barrier coatings 100 of the present invention are produced using atomic layer deposition (ALD). It is to be understood that ALD encompasses processes in which deposition of a film, from gaseous source chemicals onto a substrate surface, is based on sequential self-saturating surface reactions, for example, as described in U.S. Pat. No. 6,015,590, which is incorporated herein as if fully set forth below. Such processes can include plasma enhanced ALD (PEALD).

Just as with the primary barrier layer 102, certain conditions must be avoided by the specific ALD process used to deposit the secondary barrier layer 104. These conditions will vary based on the choice of composition used for the primary barrier layer 102. Those skilled in the art to which this disclosure pertains would understand how to pick the appropriate conditions to avoid adversely affecting the primary barrier layer 102 (and/or the organic component 110) when using ALD to deposit the secondary barrier layer 104. For example, if the primary barrier layer 102 is fabricated from a material having a low melting or decomposition temperature, then it would be understood that the ALD process used to deposit the secondary barrier layer 104 could not employ temperatures at or above the melting or decomposition temperature of the primary barrier layer 102 material.

After the secondary barrier layer 104 has been prepared, the passivation layer 106 can then be disposed thereon. The passivation layer 106 can be prepared using any of the techniques described above for the primary barrier layer 102, keeping in mind that the specific process must be sensitive to the organic component 110 and the portions of the multilayer environmental barrier coating 100 already disposed thereon.

In situations where the optional buffer layer 108 is necessary, this layer is disposed directly on the organic component 110 before the primary barrier coating is prepared. The buffer layer 108 can be prepared using any of the techniques described above for the primary barrier layer 102. Because the buffer layer 108 is disposed on the organic component 110 and cannot adversely affect the organic component 110, certain conditions, as described above for the primary barrier layer 102, must be avoided during deposition of the buffer layer 108.

Once the buffer layer 108 has been disposed on the organic component 110, the primary barrier layer 102 can be disposed (as described above) on the buffer layer 108. It is important to note that, for the purpose of the present invention, the buffer layer 108 and the primary barrier layer 102 can be formed from the same composition. If this is the case, then the process parameters for preparing each layer must be different in order for them to be considered two different layers. Otherwise, the composition is considered to be the primary barrier layer 102. When the organic component 110 is not substantially planar, and no different buffer layer 108 is used, then the primary barrier layer 102 adopts the functions of both the buffer layer 108 (i.e., to provide a planar surface) and the primary barrier layer 102.

The processes, and the resultant multilayer environmental barrier coatings 100, described above are advantageous in that the secondary barrier layer 104 is the only layer deposited by ALD so as to minimize processing time and complexity. That is, by fabricating the primary barrier layer 102 and the passivation layer 106 using a deposition technique that is more rapid than ALD, the overall processing time is reduced relative to a single layer environmental barrier coating prepared by ALD (or a multilayer environmental barrier coating having different compositions that were each prepared using ALD).

By way of example, the multilayered environmental barrier coating 100 can be disposed on the surface of an organic photovoltaic (OPV) cell. For the purpose of the present invention, an OPV cell is a device that converts optical electromagnetic radiation into electrical power. Such devices include a substrate, and a structure in which one photoactive layer (or a plurality of photoactive layers) are disposed between a pair of electrodes.

One of the electrodes of an OPV cell is transparent or semi-transparent, and can include transparent conductive oxides (TCOs), transparent conductive polymers (TCPs), inorganic oxides, mixtures of polymers and carbon nanotubes, or another suitable chemical material. Examples of TCOs include, but are not limited to, tin-doped indium oxide (ITO), fluorine-doped tin oxide (FTO), zinc oxide, aluminum- or indium-doped zinc oxide, tin oxide, magnesium-indium-oxide, cadmium-tin-oxide, and the like. Suitable TCPs include, but are not limited to, 3,4-polyethylenedioxythiophene: polystyrene sulfonate (PEDOT:PSS), polyaniline, polypyrrole doped with iodine or other Lewis acids, and other transparent or semi-transparent intrinsically conducting polymers.

The other electrode can be opaque or semi-transparent, and include a thin metal layer or a combination of a metal and a compound containing alkali metals or alkali earth metals. Examples of metals and metal alloys include, but are not limited to, aluminum, gold, silver, magnesium, calcium, copper, alloys thereof, and the like. Examples of the compound containing alkali metals or alkali earth metals include, but are not limited to lithium fluoride, lithium oxide, cesium fluoride, cesium carbonate, or other alkali metal and alkali earth metal containing materials.

The photoactive layers that can be disposed between the aforementioned pair of electrodes include combinations of organic layers or organic-based layers that are known in the art to provide a photovoltaic effect. Such photoactive layers can be formed from different organic materials, including small molecules, dendrimers, oligomers, polymers, mixtures thereof, and the like. These photoactive layers can also be formed from functionalized soluble inorganic semiconductor nanoparticles, including, but not limited to, quantum dots and nanorods of CdSe, CdTe, InP, InSb, and mixtures thereof, that can be combined with the aforementioned organic materials. The photoactive layers can be formed from neat organic or organic-based materials and fabricated sequentially on top of one another. Alternatively, the photoactive layers can be formed from mixtures of the aforementioned organic and organic-based materials. These organic and organic-based materials can be processed into thin-films using different methods including processes based on vapor phase deposition, and wet-based processes including, but not limited to, spin-coating, inkjet printing, screen-printing, other printing techniques, and the like.

An exemplary OPV cell is described in U.S. patent application Ser. No. 11/232,188, which is incorporated herein by reference as if fully set forth below.

The OPV cell can be encapsulated by the multilayer environmental barrier coating 100. Specifically, an approximately 400 nm thick buffer layer 108 of SiNₓ or SiOₓ, deposited using PECVD, is first prepared on the OPV cell. This PECVD process is a CVD process in which reactant gases are ionized or disassociated by plasma in order to promote chemical reactions which result in the deposition of a desired material. The temperature of the PECVD process is less than about 200° C.

Subsequently, a primary barrier layer 102 of SiNₓ or SiOₓ, deposited using PECVD, is then prepared on the buffer layer 108. Again, in order to be considered a two separate layers, there must be a difference between the compositions and/or the deposition parameters for each layer. The thickness of the primary barrier layer 102 in this example is about 100 nm.

Next, ALD is used to prepare an Al₂O₃ secondary barrier layer 104, having a thickness of about 10 to about 50 nm, on the primary buffer layer 102 of SiNₓ or SiOₓ.

Finally, a parylene-C passivation layer 106 is prepared on the Al₂O₃ secondary barrier layer 104 using parylene CVD. The parylene CVD process involves parylene dimer being converted to a monomer vapor at high temperature (e.g., about 650° C.) and then condensed on the sample at room temperature, thereby resulting in spontaneous polymerization and conformal deposition on the sample (and surfaces of all objects in the deposition chamber). The thickness of the parylene-C layer in this example is about 1 μm.

By way of another example, the multilayered environmental barrier coating 100 can be disposed on a flexible polymer substrate. This coated flexible polymer substrate, which will have improved barrier protection properties than the uncoated flexible polymer substrate, can be used in a variety of applications.

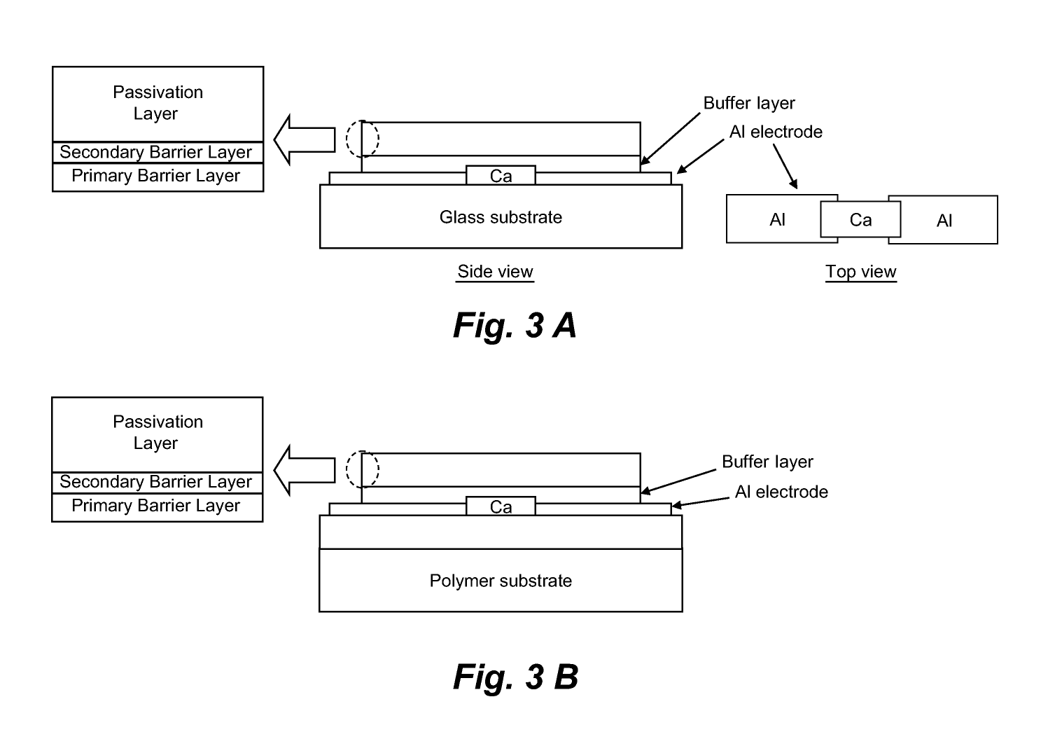

In but one illustrative example, the coated flexible polymer substrate can be used to create a flexible sandwich structure in which an organic semiconductor device is disposed. Such a structure is shown in FIG. 2 and is designated by reference numeral 200. The sandwich structure 200 is created by first preparing the multilayered environmental barrier coating 100 on the flexible substrate 210.

In this configuration, the multilayered environmental barrier coating 100 does not need the buffer layer 108. Thus, the multilayered environmental barrier coating 100 can be formed by first depositing a primary barrier layer 102 of SiNₓ or SiOₓ, using PECVD, on the flexible substrate 210. Next, an Al₂O₃ secondary barrier layer 104 having a thickness of about 10 to about 50 nm is deposited, using ALD, on the primary buffer layer 102 of SiNₓ or SiOₓ. Finally, a parylene-C passivation layer 106 is prepared on the Al₂O₃ secondary barrier layer 104 using parylene CVD.

Once the environmental barrier coating 100 has been fabricated on the flexible substrate 210, the coated flexible substrate 210 can be cut into two (or more, depending on the number of sandwich structures 200 to be created) pieces.

An organic semiconductor device 214 can be disposed on one of the pieces of the coated flexible substrate 210. The organic semiconductor device 214 can be affixed (e.g., via a chemical or physical bond) to the piece of the coated flexible substrate 210, or it can simply be placed thereon without being coupled thereto.

Next, the other piece of the coated flexible substrate 210 can be oriented such that a sandwich structure 200 is created with the organic semiconductor device 214 interposed between the two pieces of the coated flexible substrate 210. To complete the structure a seal 212 can be placed between the two environmental barrier coatings 100 of the coated flexible substrates 210. This can be accomplished using, for example, an ultraviolet curable epoxy resin. Once the seal 212 has been formed and the organic semiconductor device 214 is encapsulated by the environmental barrier coating 100, the overall sandwich structure 200 is ready for use.

The various embodiments of the present invention are further illustrated by the following non-limiting examples.

### EXAMPLES

In the following examples, various environmental barrier coatings were prepared and characterized. The primary means of assessing the effectiveness of the environmental barrier coatings in the following examples was through a measurement of the effective water vapor transmission rate (WVTR). This was carried out using a Ca corrosion test by electrical conductance monitoring.

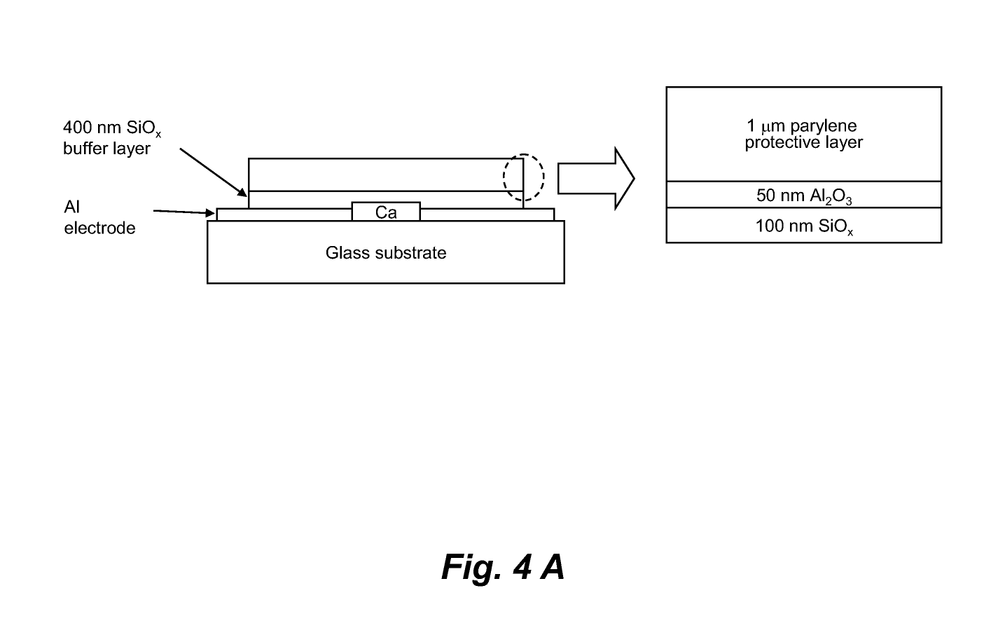

For environmental barrier coatings on glass substrates, a calcium (Ca) sensor and two aluminum (Al) electrodes were first deposited on the glass substrate. Then, the environmental barrier coating, which included a buffer layer, primary barrier layer, secondary barrier layer, and a passivation layer was deposited on top of the sensor. Such a structure is shown in FIG. 3A.

When using a flexible polymeric substrate, the Ca sensors were sealed on both sides by an environmental barrier coating because of the high permeation rate of the polymeric substrate. First, an environmental barrier coating including a primary barrier layer, secondary barrier layer, and a passivation layer was deposited on top of the polymeric substrate. Next, the Ca sensor and two Al electrodes were deposited on the environmental barrier coating. Finally, a second environmental barrier coating including a buffer layer, primary barrier layer, secondary barrier layer, and a passivation layer was deposited on top of the sensor. This structure can bee seen in FIG. 3B.

Coated Ca sensor devices were placed in an environmentally controlled chamber at about 20° C. and with a relative humidity of about 50%. The change in the conductance of the Ca sensor was measured for a period of 800 hours or greater. The change in conductance as a function of time was linear and the value of the slope dG/dt was used to calculate the effective WVTR values according to the following formula:

$$WVTR [ g \text{/} {m}^{2} \text{/} day ] = - n \times {δ}_{Ca} \times {ρ}_{Ca} \times \frac{d G}{d t} \times \frac{l}{w} \times \frac{M ( {H}_{2} O )}{M ( Ca )} \times \frac{Area ( Ca )}{Area ( Window )}$$

where n was the molar equivalent of the degradation reaction which is assumed as n=2 from the chemical reaction of Ca with water (i.e., Ca+2H₂O (n=2) →Ca(OH)₂+H₂). δ_{Ca} and ρ_{Ca} were the Ca resistivity (3.4×10⁻⁸ Ωm) and density (1.55 g/cm³), respectively. M(H₂O) and M(Ca) were the molar masses of water vapor (18 amu) and of Ca (40.1 amu), respectively. Both the ratio of the area of the Ca sensor to the area of the window for water permeation and the ratio of the length (l) to the width (w) of Ca sensor were 1, due to the geometry of the experimental set-up. Three identical Ca sensors were tested for each structure, so reported values were averaged over three devices.

### Example 1

### Preparation of Environmental Barrier Coatings on Glass Substrates

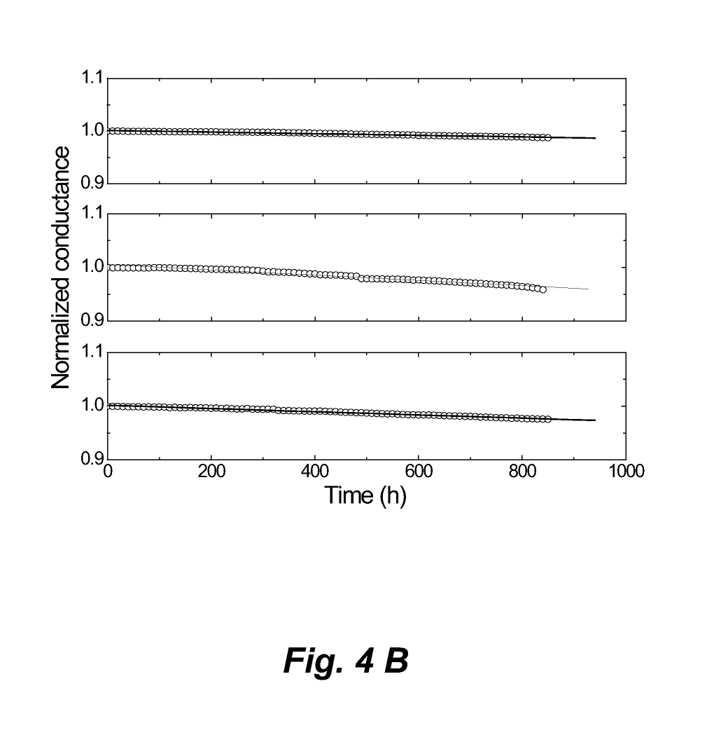

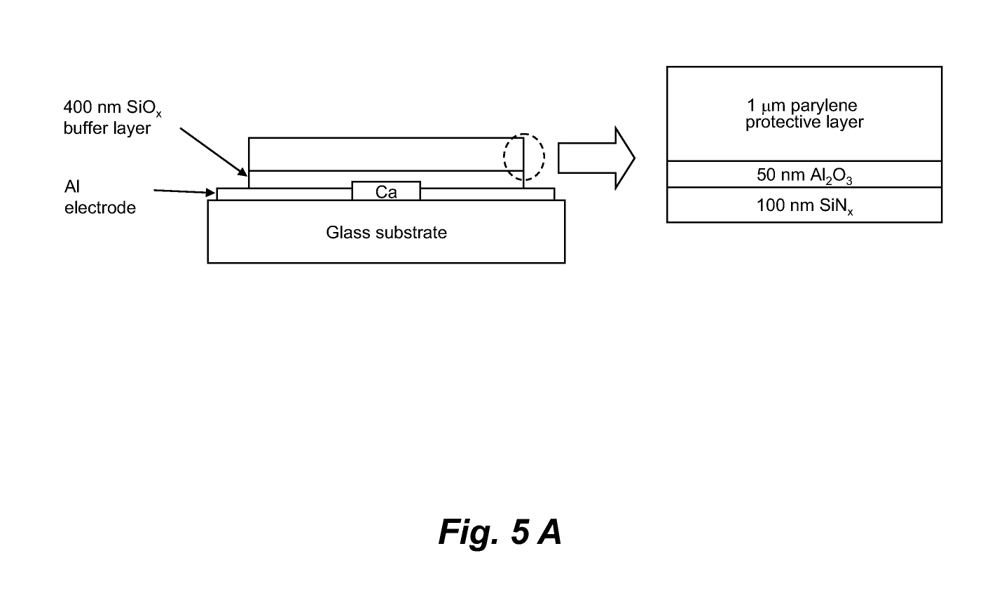

In this example, the substrate was glass, and a buffer layer comprised of an about 400 nm thick layer of SiOₓ was deposited on the calcium sensor and two aluminum electrodes using PECVD. A primary barrier layer of SiOₓ with a thickness of about 100 nm was deposited on the buffer layer using PEVCD. A secondary barrier layer of Al₂O₃, having a thickness of about 50 nm, was deposited on top of the primary barrier layer using ALD. Finally, a passivation layer of parylene with a thickness of 1 μm was deposited on top of the secondary barrier layer. The complete structure is shown in the FIG. 4A.

The precursors used for the PECVD depositions included SiH₄, N₂O, and NH₃. The flow rates of SiH₄, and N₂O were about 400 standard cubic centimeters per minute (sccm) and about 3000 sccm, respectively. The precursors were then reacted between two parallel plates in a radio frequency (RF) induced plasma to deposit SiOₓ. The electrodes were driven at a constant level of about 30 watts (W) during the entire deposition process. The pressure of the chamber was maintained at about 900 milliTorr (mTorr) and the temperature was set at 110° C. for compatibility with organic devices. The overall growth rate of SiOₓ was about 100 nanometers per minute (nm/min). The same PECVD process parameters were used to create the about 500 nm thick layer of SiOₓ. This layer was divided up as about 400 nm of a buffer layer and about 100 nm of a primary barrier layer for comparative purposes only.

After the PECVD step, the devices were placed in a sealed nitrogen-filled container and then transferred to the ALD deposition chamber (Savannah100, Cambridge Nanotech, Inc.). ALD for Al₂O₃ was performed at a temperature of about 110° C. with pulses of trimethylaluminum (TMA) for about 15 milliseconds (ms) and H₂O for about 15 ms. The chamber was pumped for about 5 seconds (s) after TMA pulses and for about 5 s after H₂O pulses for an overall growth rate of about 0.5 nm/min.

After the ALD step, the devices were placed in a sealed nitrogen-filled container and then transferred to the parylene CVD deposition chamber. Parylene with about 1 μm thickness was produced using a vapor phase deposition technique. Parylene C dimer was loaded in a vacuum chamber which was evacuated to about 1 mTorr pressure and converted to a monomer vapor at about 650° C. Condensation of the vapor on the sample at room temperature resulted in spontaneous polymerization and conformal deposition on the surfaces of all objects in the chamber for an overall growth rate of about 17 nm/min.

As shown in FIG. 4B, where the circles represent experimental data for each sample and the lines were fitted to extract effective WVTR values, the change in electrical conductance measured as a function of time yielded an effective WVTR value of about 2±1×10⁻⁵ g/m²/day.

### Example 2

### Preparation of Environmental Barrier Coatings on Glass Substrates

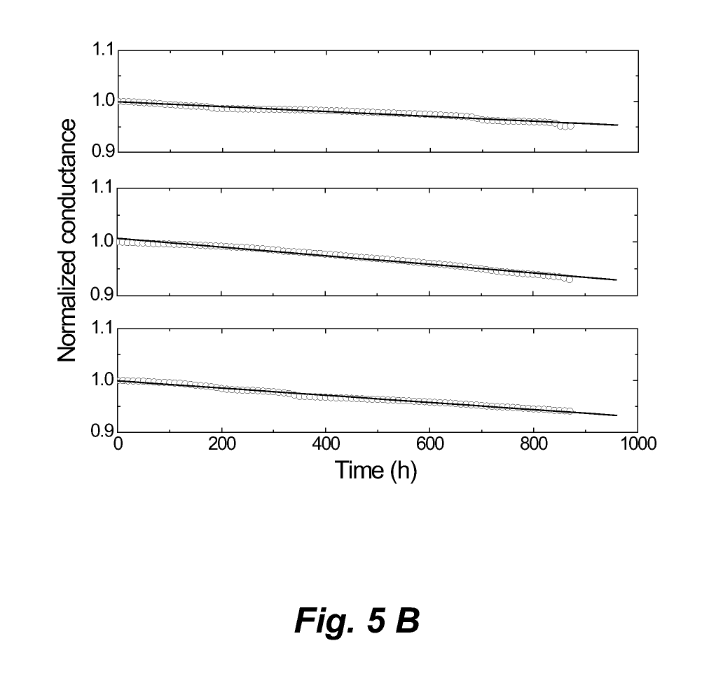

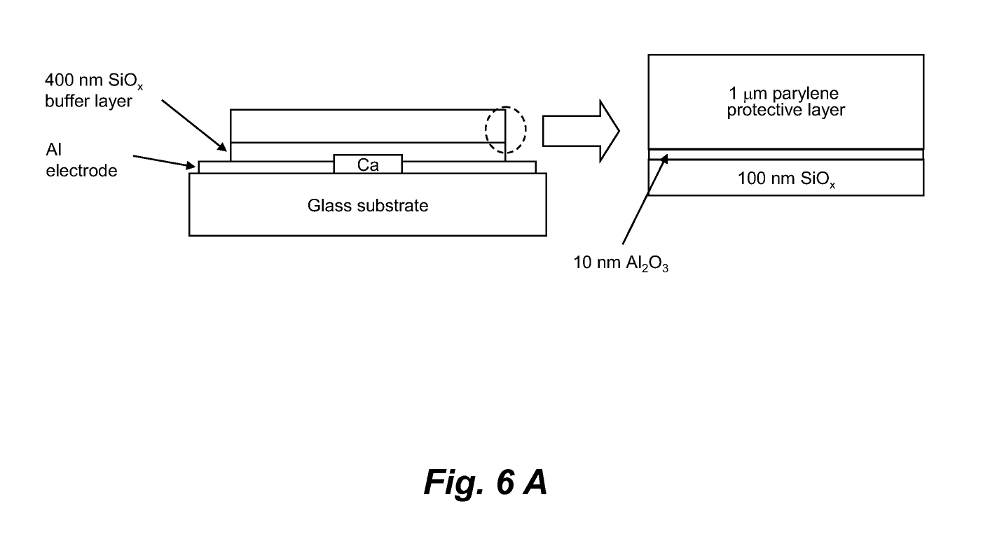

In this example, the substrate was glass, and a buffer layer comprised of an about 400 nm thick layer of SiOₓ was deposited on the calcium sensor and two aluminum electrodes using PECVD. A primary barrier layer of SiNₓ with a thickness of about 100 nm was deposited on the buffer layer using PEVCD. A secondary barrier layer of Al₂O₃, having a thickness of about 50 nm, was deposited on top of the primary barrier layer using ALD. Finally, a passivation layer of parylene with a thickness of 1 μm was deposited on top of the secondary barrier layer. The complete structure is shown in the FIG. 5A.

The precursors used for the PECVD depositions of SiOₓ included SiH₄, N₂O, and NH₃. The flow rates of SiH₄, and N₂O were about 400 sccm and about 3000 sccm, respectively. The precursors used for the PECVD depositions of SiNₓ included SiH₄, N₂, He, and NH₃. The flow rates of SiH₄, N₂, He, and NH₃ were about 200 sccm, about 720 sccm, about 560 sccm, and about 14 sccm, respectively. The precursors were then reacted between two parallel plates in a RF induced plasma to deposit the two films. The electrodes were driven at a constant level of about 30 watts (W) during the entire deposition process. The pressure of the chamber was maintained at about 900 milliTorr (mTorr) and the temperature was set at 110° C. for compatibility with organic devices. The overall growth rate of SiOₓ was about 100 nm/min, while the overall growth rate or SiNₓ was about 35 nm/min.

After the PECVD step, the devices were placed in a sealed nitrogen-filled container and then transferred to the ALD deposition chamber (Savannah100, Cambridge Nanotech, Inc.). ALD for Al₂O₃ was performed at a temperature of about 110° C. with pulses of TMA for about 15 ms and H₂O for about 15 ms. The chamber was pumped for about 5 s after TMA pulses and for about 5 s after H₂O pulses for an overall growth rate of about 0.5 nm/min.

After the ALD step, the devices were placed in a sealed nitrogen-filled container and then transferred to the parylene CVD deposition chamber. Parylene with about 1 μm thickness was produced using a vapor phase deposition technique. Parylene C dimer was loaded in a vacuum chamber which was evacuated to about 1 mTorr pressure and converted to a monomer vapor at about 650° C. Condensation of the vapor on the sample at room temperature resulted in spontaneous polymerization and conformal deposition on the surfaces of all objects in the chamber for an overall growth rate of about 17 nm/min.

As shown in FIG. 5B, where the circles represent experimental data and the lines were fitted to extract effective WVTR values, the change in electrical conductance measured as a function of time yielded an effective WVTR value of about 3±2×10⁻⁵ g/m²/day.

### Example 3

### Preparation of Environmental Barrier Coatings on Glass Substrates

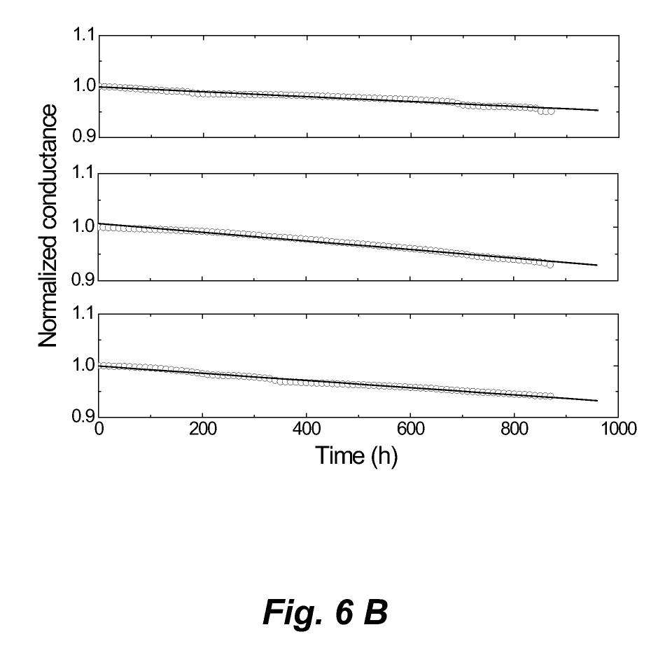

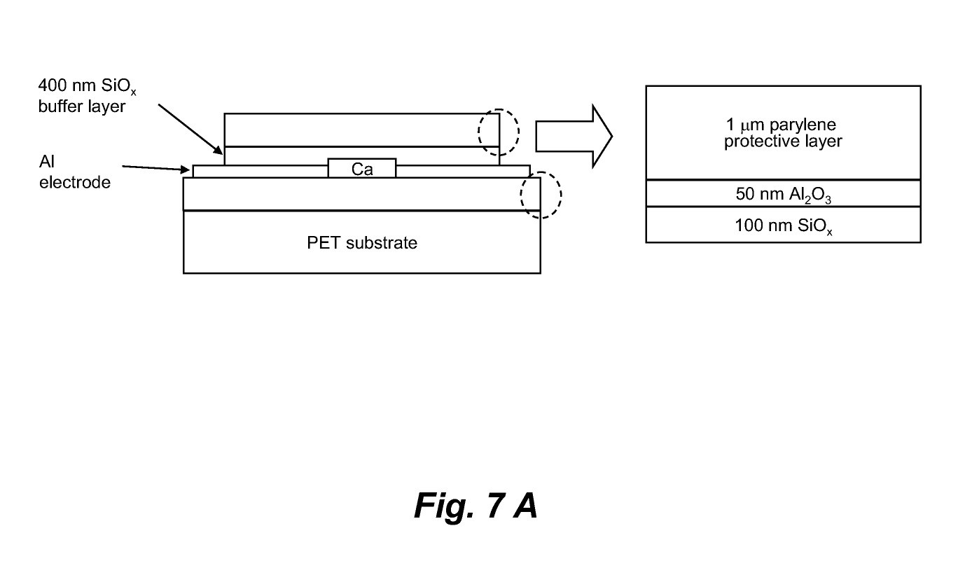

In this example, a device was prepared exactly as described in Example 1, with the exception that the secondary barrier layer of Al₂O₃, grown using ALD, was prepared with a thickness of about 10 nm. A schematic illustration of this structure is shown in FIG. 6A.

As shown in FIG. 6B, where the circles represent experimental data and the lines were fitted to extract effective WVTR values, the change in electrical conductance measured as a function of time yielded an effective WVTR value of about 4±0.5×10⁻⁵ g/m²/day.

### Example 4

### Preparation of Environmental Barrier Coatings on Flexible Substrates

In this example, the substrate was poly(ethyleneterephtalate) (PET), having a thickness of about 100 μm. As described above, the Ca sensors were sealed on both sides by an environmental barrier coating because of the high permeation rate of the PET substrate.

First, an environmental barrier coating including a primary barrier layer, secondary barrier layer, and a passivation layer was deposited on top of the polymeric substrate. Specifically, a primary barrier layer of SiOₓ with a thickness of about 100 nm, was deposited on the PET substrate using PEVCD. A secondary barrier layer of Al₂O₃, having a thickness of about 50 nm, was deposited on top of the primary barrier layer using ALD. Finally, a passivation layer of parylene with a thickness of 1 μm was deposited on top of the secondary barrier layer.

Afterwards, the Ca sensor and two Al electrodes were deposited on the parylene passivation layer of the first environmental barrier coating.

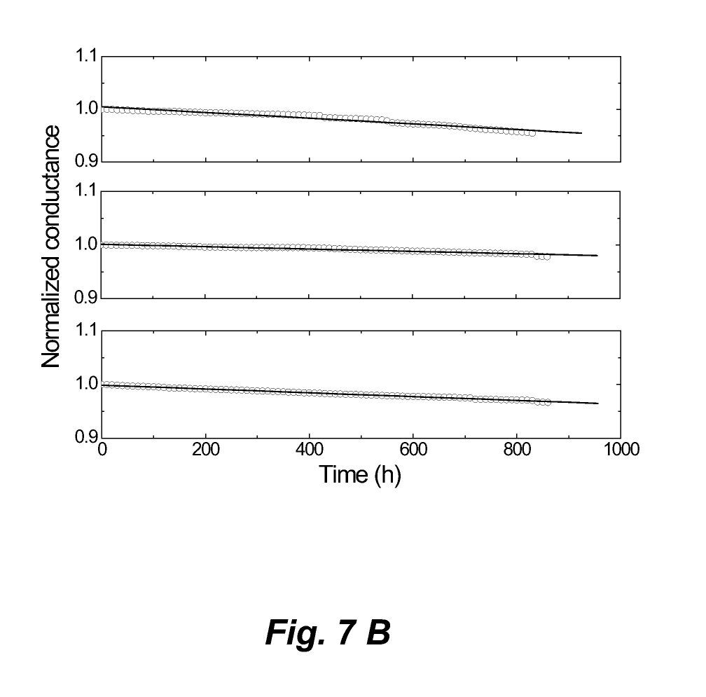

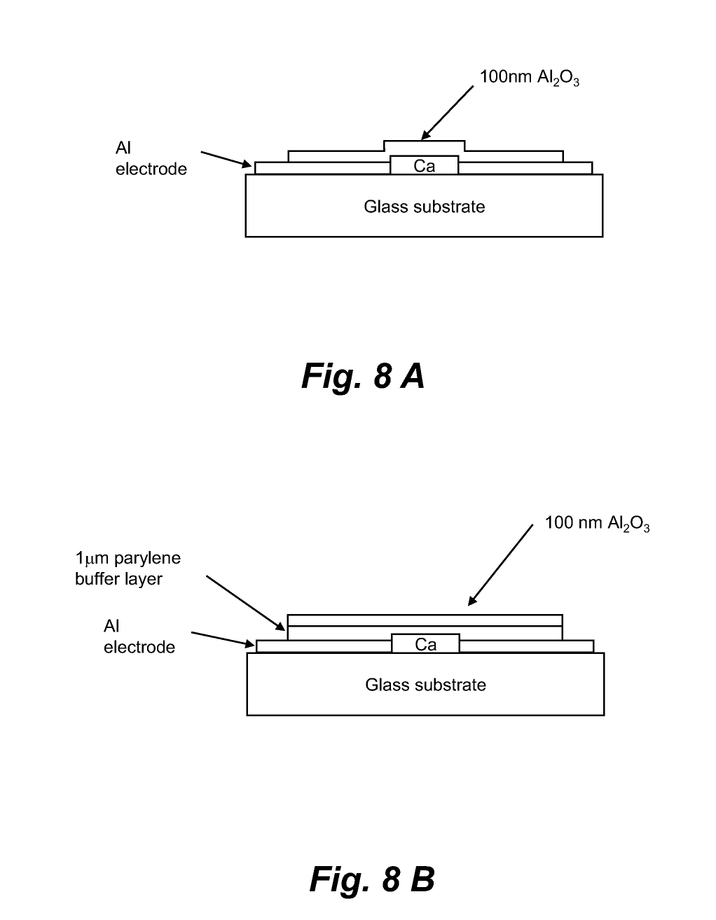

Next, a second environmental barrier coating including a buffer layer, primary barrier layer, secondary barrier layer, and a passivation layer was deposited on top of the calcium sensor and two aluminum electrodes. That is, a buffer layer comprised of an about 400 nm thick layer of SiOₓ was deposited on the glass substrate using PECVD. A primary barrier layer of SiN_{X} with a thickness of about 100 nm was deposited on the buffer layer using PEVCD. A secondary barrier layer of Al₂O₃, having a thickness of about 50 nm, was deposited on top of the primary barrier layer using ALD. Finally, a passivation layer of parylene with a thickness of 1 μm was deposited on top of the secondary barrier layer. The complete structure is shown in the FIG. 7A.

The first environmental barrier coating was prepared exactly as described in Example 1, with the exception that the buffer layer was not needed. Thus the SiOₓ layer was only 100 nm thick, rather than 500 nm thick. The second environmental barrier coating was prepared exactly as described in Example 1.

As shown in FIG. 7B, where the circles represent experimental data and the lines were fitted to extract effective WVTR values, the change in electrical conductance measured as a function of time yielded an effective WVTR value of about 3±1×10⁻⁵ g/m²/day.

### Example 5

### Comparison of Environmental Barrier Coatings

In this example, the effects of a buffer layer and/or a passivation layer on the performance of various environmental barrier coatings was studied. In particular three different structures were examined.

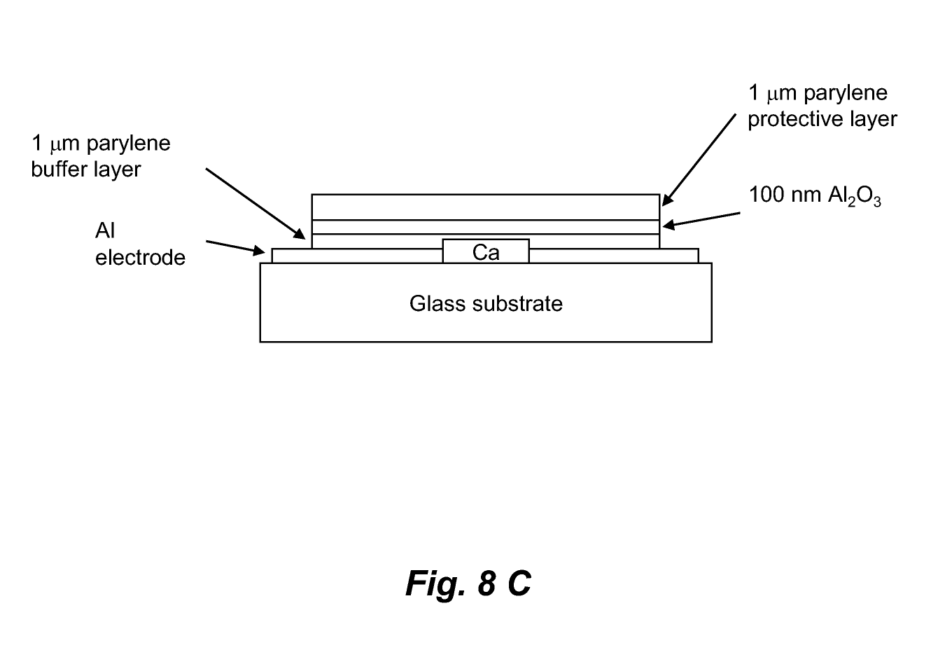

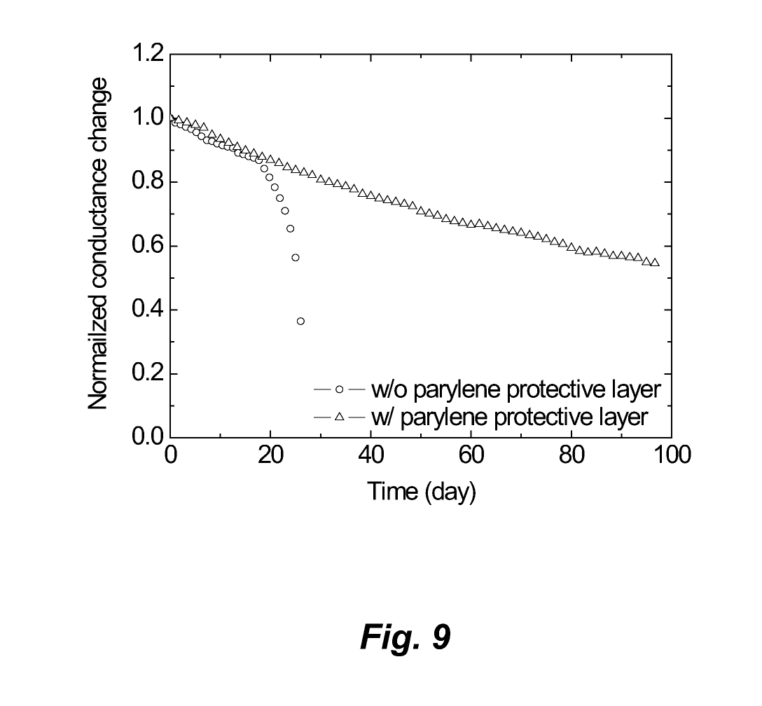

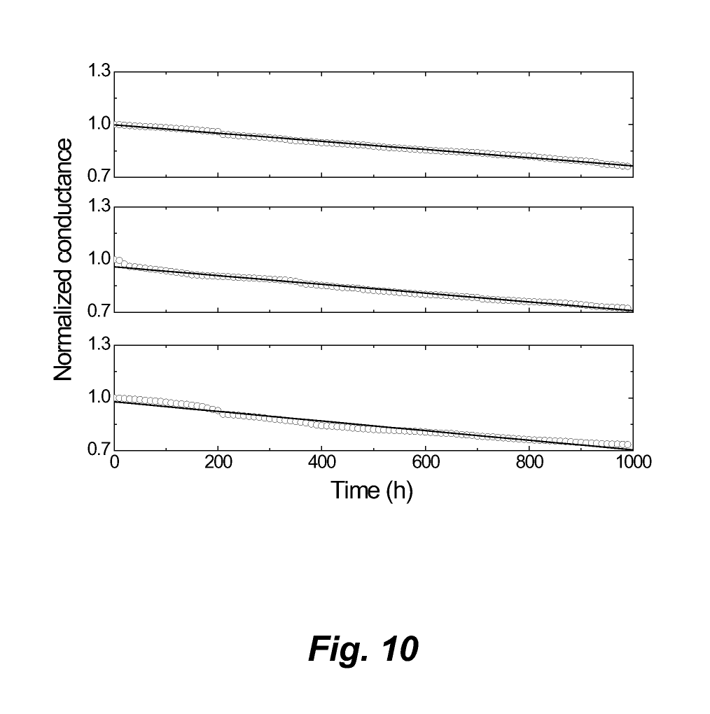

First, as shown in FIG. 8A, is a structure having a single Al₂O₃ layer, deposited by ALD on the Ca sensor and two Al electrodes, to a thickness of about 100 nm. The ALD process parameters were exactly as described for the ALD step in Example 1, with the exception that this layer was grown to a thickness of about 100 nm.

A second structure, which is shown in FIG. 8B, was prepared to have an about 1 μm parylene buffer layer deposited on the Ca sensor and two Al electrodes. This was followed by an ALD step where an about 100 nm thick film of Al₂O₃ was grown. The parylene buffer layer growth parameters were exactly as described in Example 1. The ALD process parameters were exactly as described for the ALD step in Example 1, with the exception that this layer was grown to a thickness of about 100 nm.

As shown in FIG. 8C, the third structure was prepared to have parylene buffer layer, with a thickness of about 1 μm, deposited on the Ca sensor and two Al electrodes. This was followed by an ALD step where an about 100 nm thick film of Al₂O₃ was grown. On top of the Al₂O₃ layer, there was grown a passivation layer of parylene, having a thickness of about 1 μm. The two parylene layers were grown under the same conditions described in Example 1. Similarly, the ALD process parameters were exactly as described for the ALD step in Example 1, with the exception that this layer was grown to a thickness of about 100 nm.

It was revealed that the encapsulated Ca sensor of FIG. 8A degraded rapidly and non-uniformly owing to delamination of the Al₂O₃ environmental barrier coating from the Ca sensor.

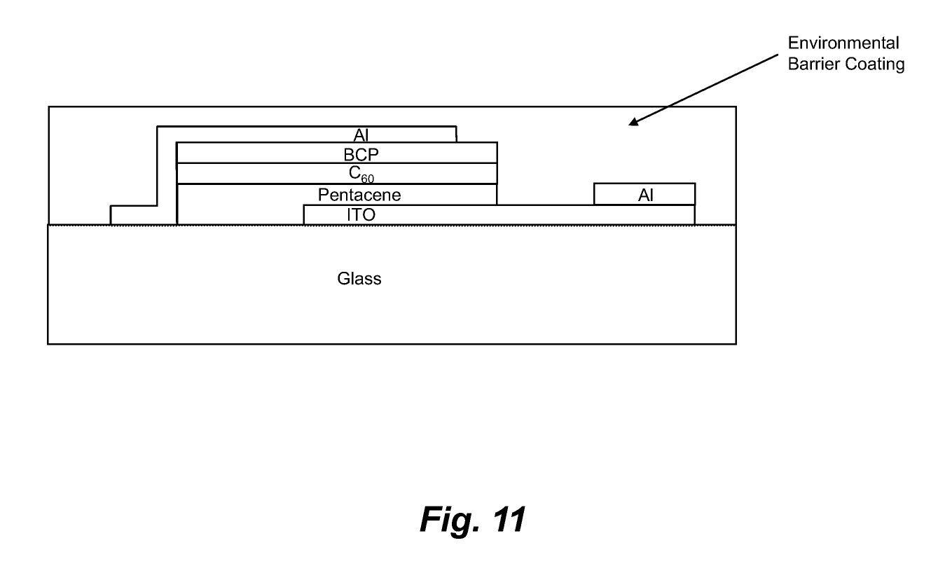

By applying the buffer layer between the ALD layer and the Ca sensor with the two Al electrodes, as shown in the FIG. 8B, delamination was circumvented. After overcoming the delamination problem, an attempt was made to test the structure shown in FIG. 8B over the course of about 10 weeks. This long term test, however, revealed that Al₂O₃ could be corroded easily by moisture in the atmosphere. The barrier coating lost significant conductivity after about 2 weeks. In contrast, the structure of FIG. 8C was not affected by moisture in the atmosphere, and did not experience a significant decrease in conductivity after about 2 weeks. These results are shown graphically in FIG. 9.

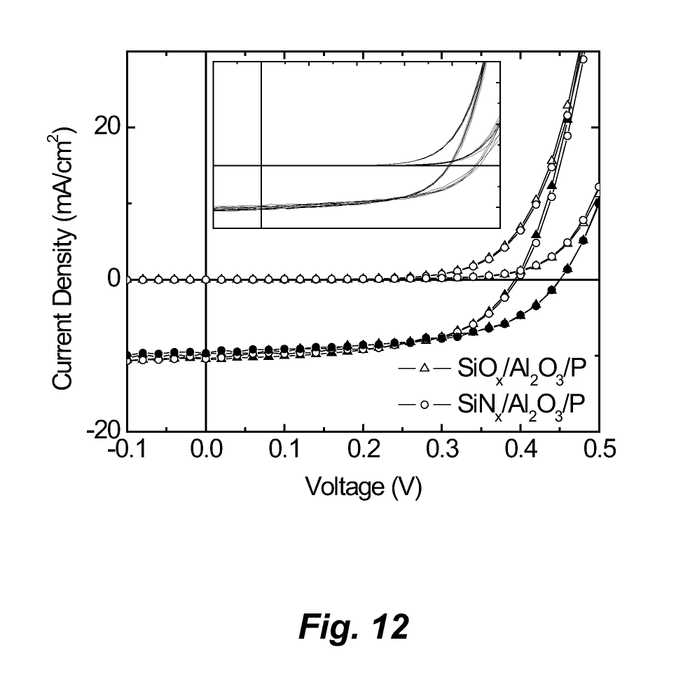

In fact, the structure of FIG. 8C exhibited stable and consistent performance, resulting in a steady decrease in the change in conductance. As shown in FIG. 10, the change in electrical conductance measured as a function of time yielded an effective WVTR value of 1±0.3×10⁻⁴ g/m² day.

The results of this long-term test indicate that the largest contributor to resistance against water vapor and oxygen comes from the Al₂O₃ layer. The parylene buffer layer and the parylene protective layer do not affect the overall barrier performance as significantly as does the Al₂O₃ layer.

### Example 6

### Encapsulated Organic Photovoltaic Cells

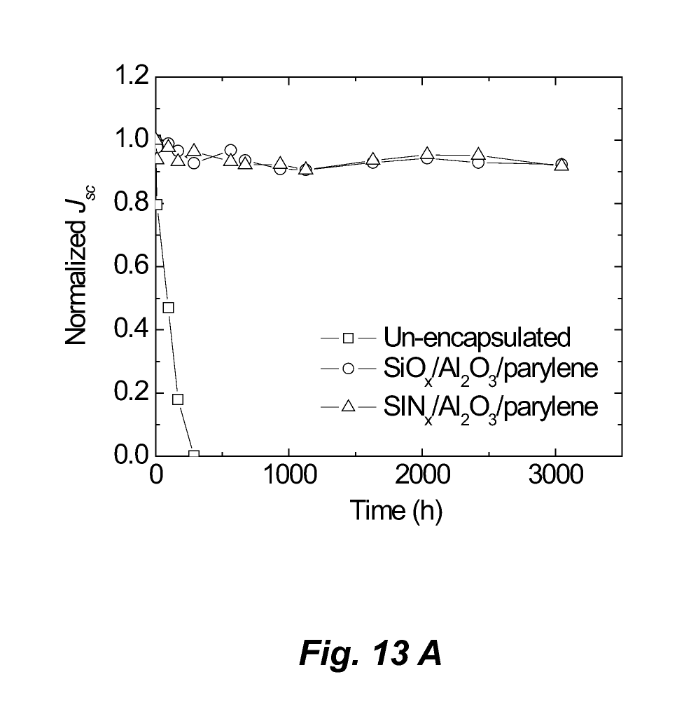

In this example, OPV cells were encapsulated with environmental barrier coatings and characterized. The OPV cell is as described in U.S. patent application Ser. No. 11/232,188, and is shown schematically in FIG. 11. Specifically, the geometry of the OPV cell, which was fabricated on a glass substrate, comprised a layer of ITO; a layer of pentacene with a thickness of about 50 nm disposed in part on a portion of the layer of ITO and in part on the glass substrate; a layer of C₆₀ with a thickness of about 40 nm disposed on the pentacene layer; a layer of bathocuproine (BCP) with a thickness of about 7 nm disposed on the C₆₀; and a layer of Al disposed on a portion of the BCP layer. The active device area was about 0.1 square centimeters (cm²).

After the OPV cells were fabricated, two sets of environmental barrier coatings were prepared. First, environmental barrier coatings were prepared as described in Example 1, with the exception that the OPV cells were coated instead of the Ca sensor and 2 Al electrodes. The other set of environmental barrier coatings were prepared as described in Example 2, again with the exception that the OPV cells were coated instead of the Ca sensor and 2 Al electrodes.

After encapsulation with the environmental barrier coatings, the encapsulated OPV cell devices were stored in an environmentally controlled chamber. For testing, the samples were loaded into a nitrogen-filled glove box where a 175 W Xenon lamp (ASB-XE-175EX, CVI) was used as a broadband light source (350-900 nm) with an irradiance of approximately 100 mW/cm².

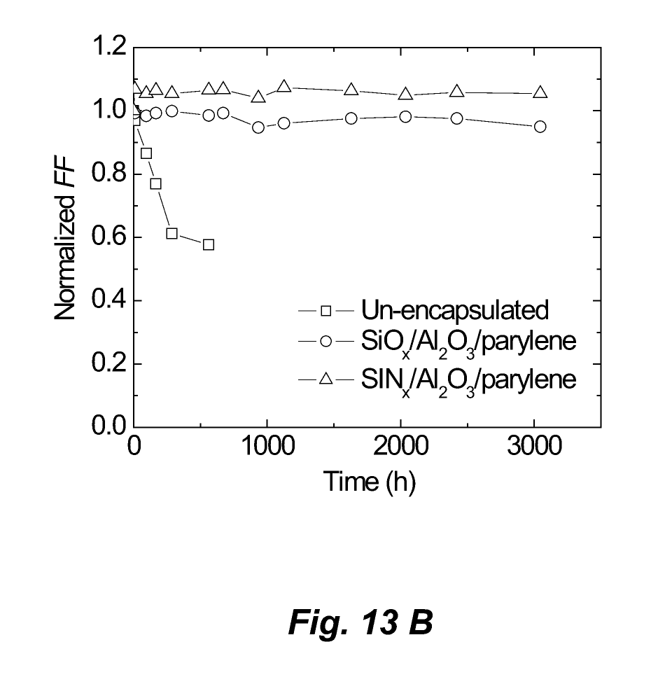

The electrical characteristics of six devices on two glass substrates were measured in the dark and under illumination before and after undergoing encapsulation. FIG. 12 is a graph that shows the characteristics for representative devices encapsulated with SiOₓ (100 nm)/Al₂O₃ (50 nm)/parylene (1 μm) (triangular shapes) and SiNₓ (100 nm)/Al₂O₃ (50 nm)/parylene (1 μm) (circle shapes). When averaged over six devices, the open-circuit voltage (V_{OC}) and the fill factor (FF) both increased from 391±3 mV and 0.55±0.01 to 449±7 mV and 0.54±0.02 after encapsulation. Short-circuit current density (J_{SC}) changed from 10.8±0.4 mA/cm² to 9±1.0 mA/cm² due to the slight change in irradiance before and after encapsulation and remained constant over a long period of time.

Overall, power conversion efficiency (η) under the broadband light source increased from 3.2±0.1% before encapsulation to 3.4±0.1% after. Under AM 1.5 G illumination (93369, Oriel), η after the encapsulation process was estimated to be 1.2±0.1%. The electrical characteristics for six devices tested, as seen in the inset of FIG. 12, show a reproducible trend for all of the devices that underwent the PECVD, ALD and parylene CVD process steps.

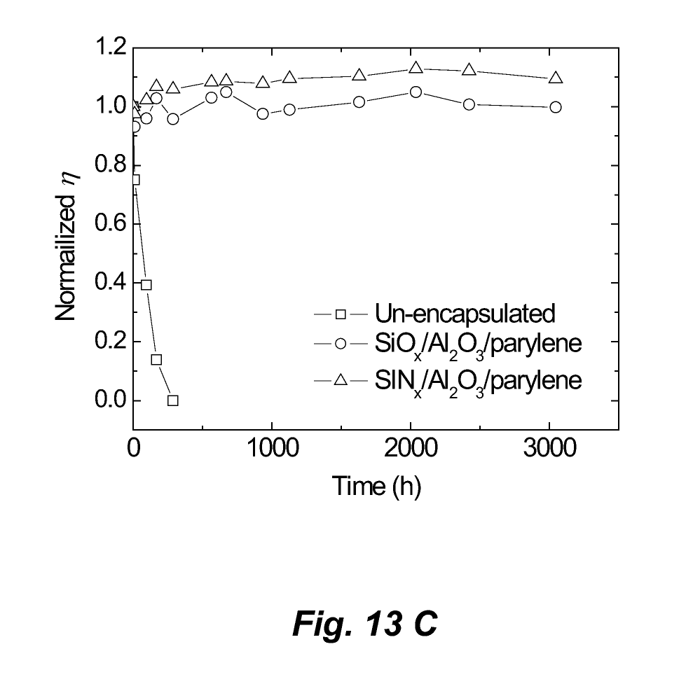

Next, the effectiveness of the environmental barrier coatings were tested over time. Samples were stored in an environmentally controlled chamber at 20° C. and 50% R.H. Table I lists the initial performance characteristics of the cells presented here after encapsulation. The cells were all fabricated during the same batch, and η was slightly higher for the cells with encapsulation process because of the thermal annealing effects associated with the PECVD and ALD process. FIGS. 13A-C show how the key performance parameters of η, FF, and J_{SC} changed relative to their initial values after exposure to ambient atmosphere for the two types of encapsulated OPV cells as well as un-encapsulated OPV cells.

TABLE I
Initial performance characteristics of
solar cells tested after encapsulation

| | | J_{SC} | | |
|---|---|---|---|---|
| Encapsulation | η (%) | (mA/cm²) | FF | V_{OC} (mV) |
| None | 3.2 ± 0.0 | 11.6 ± 0.3 | 0.54 ± 0.01 | 387 ± 1 |
| SiOx/Al₂O₃/parylene | 3.2 ± 0.1 | 10.4 ± 0.0 | 0.50 ± 0.01 | 392 ± 2 |
| SiNx/Al₂O₃/parylene | 3.1 ± 0.1 | 10.4 ± 0.2 | 0.54 ± 0.01 | 394 ± 2 |

As was generally expected for organic devices, the performance of the OPV cells with no encapsulation degraded the fastest. After only 10 h, η and J_{SC} dropped to less than 20% of their initial values. This kind of rapid degradation in overall performance has been seen with other materials and is a reminder of how important it is to adequately encapsulate organic devices.

Detailed measurements were only taken for devices without encapsulation that had not been annealed, but it should be mentioned that measurements of annealed devices without encapsulation have not shown any significant change in air stability.

Devices encapsulated with the environmental barrier coatings based on both SiOₓ and SiN_{X}, had η, FF and J_{SC} within 5% of the initial values after 3,000 h of exposure to ambient atmosphere (at 20° C. and 50% relative humidity). The reduced rate of deterioration was thought to be caused by the coating effectively blocking oxygen and water from reaching and reacting with the active materials of the OPV cells. Some of main performance parameters fluctuated during the measurement, but these fluctuations were suspected to be related to contact issues at the electrodes when making repeated contacts to the devices for testing.

This example demonstrates that encapsulation with an environmental barrier coating according to some embodiments of the present invention can provide OPV cells with effective protection from ambient air and moisture, which is regarded as an important prerequisite for a long cell lifetime. The processes disclosed herein have been shown to also improve the performance of pentacene/C₆₀ based solar cells by increasing V_{OC} and η similarly to what is observed after annealing this type of organic solar cell. The encapsulation were further improved by using a plurality of layers and by combining the dielectric layers processed by ALD with stress relaxing layers such as parylene. The thin ALD layers were combined with layers fabricated using other vacuum deposition techniques.

The above examples are not intended to be limiting, but instead provide illustrative examples of environmental barrier coatings fabricated according to some embodiments of the present invention. For example, the environmental barrier coatings of Examples 1-4 and 6 illustrate the advantages of the various embodiments of the present invention.

The embodiments of the present invention are not limited to the particular formulations, process steps, and materials disclosed herein as such formulations, process steps, and materials may vary somewhat. Moreover, the terminology employed herein is used for the purpose of describing exemplary embodiments only and the terminology is not intended to be limiting since the scope of the various embodiments of the present invention will be limited only by the appended claims and equivalents thereof.

Therefore, while embodiments of this disclosure have been described in detail with particular reference to exemplary embodiments, those skilled in the art will understand that variations and modifications can be effected within the scope of the disclosure as defined in the appended claims. Accordingly, the scope of the various embodiments of the present invention should not be limited to the above-discussed embodiments, and should only be defined by the following claims and all equivalents.

1. An environmental barrier coating, comprising:
a primary barrier layer disposed on a surface of an organic component, wherein the primary barrier layer is a non-conformal layer;
a secondary barrier layer disposed on the primary barrier layer, wherein the secondary barrier layer is a conformal layer formed by atomic layer deposition; and
a passivation layer disposed on the secondary barrier layer, wherein the passivation layer reduces exposure of the primary and secondary barrier layers to moisture and oxygen.

2. The environmental barrier coating of claim 1, further comprising a buffer layer interposed between the primary barrier layer and the surface of the organic component, wherein the buffer layer is a non-conformal layer.

3. The environmental barrier coating of claim 1, wherein one or both of the primary barrier layer and the passivation layer is formed from a metal oxide, metal nitride, metal oxynitride, or a combination comprising at least one of the foregoing.

4. The environmental barrier coating of claim 1, wherein one or both of the primary barrier layer and the passivation layer is formed from a fluoropolymer, polyolefin, epoxide polymer, acrylate polymer, polyimide, polyurethane, silicone polymer, parylene, a copolymer thereof, or a combination comprising at least one of the foregoing.

5. The environmental barrier coating of claim 4, wherein the passivation layer is formed from parylene C.

6. The environmental barrier coating of claim 1, wherein the primary barrier layer has a thickness of about 20 nanometers to about 500 nanometers, the secondary barrier layer has a thickness of less than or equal to about 50 nanometers, the passivation layer has a thickness of at least about 100 nm, or a combination comprising at least two of the foregoing.

7. The environmental barrier coating of claim 1, wherein the environmental barrier coating has an effective water vapor transmission rate of less than 10⁻⁴ grams per square meter per day measured at about 20 degrees Celsius and at about 50 percent relative humidity, and/or the environmental barrier coating has an effective water vapor transmission rate of less than 10⁻⁴ grams per square meter per day for temperatures up to about 60 degrees Celsius and relative humidities up to about 90 percent relative humidity.

8. The environmental barrier coating of claim 1, wherein the secondary barrier layer is formed from a metal oxide, metal nitride, metal oxynitride, metal sulfide, or a combination comprising at least one of the foregoing.

9. The environmental barrier coating of claim 1, wherein the passivation layer is a conformal layer.

10. The environmental barrier coating of claim 1, wherein the organic component is flexible.

11. The environmental barrier coating of claim 1, wherein the organic component is an organic light-emitting diode, organic light emitting display, organic photovoltaic cell, an organic photovoltaic module, organic memory device, organic field-effect transistor, or an organic electronic circuit comprising at least one of the foregoing organic components.

12. An environmental barrier coating, comprising:
a primary barrier layer disposed on a surface of an organic component, wherein the primary barrier layer is a non-conformal layer formed by plasma enhanced chemical vapor deposition having a thickness of about 20 nanometers to about 500 nanometers;
a secondary barrier layer disposed on the primary barrier layer, wherein the secondary barrier layer is a conformal layer formed by atomic layer deposition having a thickness of less than or equal to about 50 nanometers; and
a passivation layer disposed on the secondary barrier layer, wherein the passivation layer reduces exposure of the primary and secondary barrier layers to moisture and oxygen.

13. The environmental barrier coating of claim 12, further comprising a buffer layer interposed between the primary barrier layer and the surface of the organic component, wherein the buffer layer is a non-conformal layer.

14. The environmental barrier coating of claim 12, wherein the thickness of the secondary barrier layer is less than or equal to about 15 nanometers.

15. A method of fabricating an environmental barrier coating, the method comprising:
disposing a non-conformal primary barrier layer on a surface of an organic component;
disposing a conformal secondary barrier layer on the primary barrier layer by atomic layer deposition; and
disposing a passivation layer on the secondary barrier layer, wherein the passivation layer reduces exposure of the primary and secondary barrier layers to moisture and oxygen.

16. The method of claim 15, further comprising disposing a buffer layer on the surface of the organic component, wherein the non-conformal primary buffer layer is then disposed on the buffer layer.

17. The method of claim 15, wherein the primary barrier layer is disposed on the surface of the organic component by plasma enhanced chemical vapor deposition.

18. The method of claim 15, wherein the primary barrier layer, secondary barrier layer, and passivation layer are disposed at a temperature of less than or equal to about 300 degrees Celsius.

19. The method of claim 15, wherein the organic component is a flexible polymer substrate, an organic light-emitting diode, organic light emitting display, organic photovoltaic cell, an organic photovoltaic module, organic memory device, organic field-effect transistor, or an organic electronic circuit comprising at least one of the foregoing organic components.

20. The method of claim 15, further comprising:
disposing an organic semiconductor device on the passivation layer;
disposing a different non-conformal primary barrier layer on the organic semiconductor device;
disposing a different conformal secondary barrier layer on the different primary barrier layer by atomic layer deposition; and
disposing a different passivation layer on the different secondary barrier layer, wherein the different passivation layer reduces exposure of the different primary and different secondary barrier layers to moisture and oxygen.

21. The method of claim 20, wherein the non-conformal primary barrier layer and the different non-conformal primary barrier layer have the same composition, the conformal secondary barrier layer and the different conformal secondary barrier layer have the same composition, the passivation layer and the different passivation layer have the same composition, or a combination comprising at least two of the foregoing.

22. The method of claim 20, further comprising disposing a buffer layer on the organic semiconductor device, wherein the different non-conformal primary buffer layer is then disposed on the buffer layer.
